(19) United States
(12) Patent Application Publication
(10) Pub. No.: US 2026/0206577 A1
(43) Pub. Date: Jul. 16, 2026

(54) E-FUSE CELL CIRCUIT AND SEMICONDUCTOR DEVICE INCLUDING THE SAME

(71) Applicant: SK hynix Inc, Gyeonggi-do (KR)

(72) Inventor: Jae Hwan SEO, Gyeonggi-do (KR)

(21) Appl. No.: 19/087,581

(22) Filed: Mar. 24, 2025

(30) Foreign Application Priority Data
Jan. 16, 2025 (KR) 10-2025-0006886

(51) Int. Cl. H10W 20/49; G11C 17/16; H10B 20/25; G11C 17/18

(52) U.S. Cl. CPC H10W 20/493; G11C 17/16; H10B 20/25; G11C 17/18

(57) ABSTRACT

An E-fuse cell circuit may include at least one E-fuse cell circuit block spaced apart in a first direction. A power gate driver group and a selection gate driver group in the E-fuse cell circuit block may include a plurality of power gate driver units arranged at a first pitch interval in upward and downwards direction from a second axis extending in a second direction, respectively, based on a center point of intersection between a first axis extending the first direction, and the second axis, and a plurality of selection gate driver units arranged at a second pitch interval different from the first pitch interval.

### CROSS-REFERENCES TO RELATED APPLICATION

The present application claims priority under 35 U.S.C. § 119(a) to Korean application number 10-2025-0006886, filed on January 16, 2025, which is incorporated herein by reference in its entirety.

### BACKGROUND

### 1. Technical Field

Embodiments of the present disclosure relate to an electrical device, and more particularly to an E-fuse cell circuit and a semiconductor device including the E-fuse cell circuit.

### 2. Related Art

With increasing integration of a semiconductor device, attempts may be made to scale down each of various circuit configurations that make up the semiconductor device. Efforts are ongoing to efficiently place scaled-down circuit configurations within the limited area of the semiconductor device.

Among the various circuit configurations of the semiconductor device, an electrical fuse (hereinafter, E-fuse) cell circuit may include an E-fuse cell array including a plurality of E-fuse cells, a power gate driver for driving a selected E-fuse cell and a selected gate driver. Generally, one E-fuse cell has a first transistor for storing fuse data having a binary value (1 or 0) and a second transistor for activating or deactivating the corresponding E-fuse cell connected. The first transistor and the second transistor may be serially connected with each other.

A power gate driver of the E-fuse cell circuit may output a voltage to the gate of the first transistor in each of the E-fuse cells. A selection gate driver may output a voltage to the gate of the second transistor in each of the E-fuse cells. Since the voltage outputted by the power gate driver to the E-fuse cell may be more than twice as large as the voltage output by the selection gate driver to the E-fuse cell, the power gate driver may be limited in scaling down due to reliability issues. Therefore, it may be difficult to integrate the E-fuse cell array, the selection gate driver and the power gate driver due to a mismatch among heights of the E-fuse cell array, the selection gate driver and the power gate driver.

Therefore, there may be a need for efficient layout technique for the E-fuse cell arrays, the selection gate drivers and the power gate drivers that may reduce area while avoiding reliability issues.

### SUMMARY

Embodiments of the present disclosure provide an E-fuse cell circuit that is capable of preventing reliability issues from occurring in a power gate driver while preventing an increase in an area of a selection gate driver.

Embodiments of the present disclosure also provide a semiconductor device including the E-fuse cell circuit.

According to embodiments of the present disclosure, there may be provided an E-fuse cell circuit. The E-fuse cell circuit may include a plurality of E-fuse cell circuit blocks arranged spaced apart with each other in a first direction. Each of the plurality of E-fuse cell circuit blocks may include an E-fuse cell group, a selection gate driver group and a power gate drive group. The E-fuse cell group may include a plurality of E-fuse cells. The selection gate driver group may be disposed adjacent to the E-fuse cell group along a second direction perpendicular to the first direction. The selection gate driver group may include a plurality of selection gate driver units configured to provide a selection gate voltage signal to at least one E-fuse cell selected among the plurality of E-fuse cells. The power gate driver group disposed adjacent to the selection gate driver group along the second direction. The power gate driver group may include a plurality of power gate driver units configured to provide a power gate voltage signal to the at least one E-fused cell. The plurality of power gate driver units may be arranged with a first pitch interval in an upwardly and downwardly direction from a second axis extending along the second direction, based on a center point of an intersection between the second axis and a first axis extending the first direction. The plurality of selection gate driver units may be arranged with a second pitch interval in upward and downward directions from the second axis based on the center point, the second pitch interval being different from the first pitch interval.

According to embodiments of the present disclosure, there may be provided a semiconductor device. The semiconductor device may include at least one E-fuse cell group each including a plurality of E-Fuse cells, at least one power gate drive group, and at least one selection gate driver group. The at least one power gate driver group may correspond to the at least one E-fuse cell group. The at least one power gate drive group may include a plurality of power gate driver units. The at least one selection gate driver group may correspond to the at least one E-fuse cell group. The at least one selection gate drive group may include a plurality of selection gate driver units. The at least one power gate driver group and the at least one selection gate driver group may be arranged left and right based on a first axis extending in a first direction. The plurality of power gate driver units may be arranged at a first pitch interval in upward and downward directions from a second axis perpendicular to the first axis. The plurality of selection gate driver units may be arranged in the upward and downward direction of the second axis from a second pitch interval different from the first pitch.

According to embodiments of the present disclosure, the plurality of power gate driver units and the plurality of selection gate driver units may be each arranged in a first region and a second region separated by the first axis among four regions divided based on the center point where the first axis and the second axis may be intersected with each other, and arranged to have the different pitch interval.

In this case, the pitch interval may include a height of the units and the space between the units, and by arranging the space between the power gate driver units to be smaller than the space between the selection gate driver units, it may be possible to efficiently arrange the E-fuse cell array, the selection gate driver and the power gate driver within a limited area while satisfying reliability of the power gate driver.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is a view illustrating a semiconductor device in accordance with embodiments of the present disclosure;

FIG. 2 is a view illustrating an E-fuse cell circuit in FIG. 1;

FIG. 3 is an enlarged view of a portion “A” in FIG. 2;

FIG. 4 is a layout illustrating a power gate driver unit in accordance with embodiments of the present disclosure;

FIG. 5 is a layout illustrating a selection gate driver unit in accordance with embodiments of the present disclosure;

FIG. 6 is a layout and a circuit diagram illustrating a power gate voltage activation circuit and a power gate voltage output circuit of a power gate driver unit in accordance with embodiments of the present disclosure; and

FIG. 7 is a layout and a circuit diagram illustrating a selection gate voltage activation circuit and a selection gate voltage output circuit of a selection gate driver unit in accordance with embodiments of the present disclosure.

### DETAILED DESCRIPTION

The advantages and features of the present disclosure, and methods of achieving them, will become apparent upon reference to the embodiments described in detail with reference to the accompanying drawings. However, the present invention is not limited to the embodiments disclosed herein, but may be embodied in many different forms. These embodiments are provided merely to make the present disclosure complete and to give a complete picture of the scope of the present disclosure to one of ordinary skill in the art. The dimensions and relative sizes of the layers and regions in the drawings may be exaggerated for clarity of description. Throughout the specification, like reference numerals refer to like components.

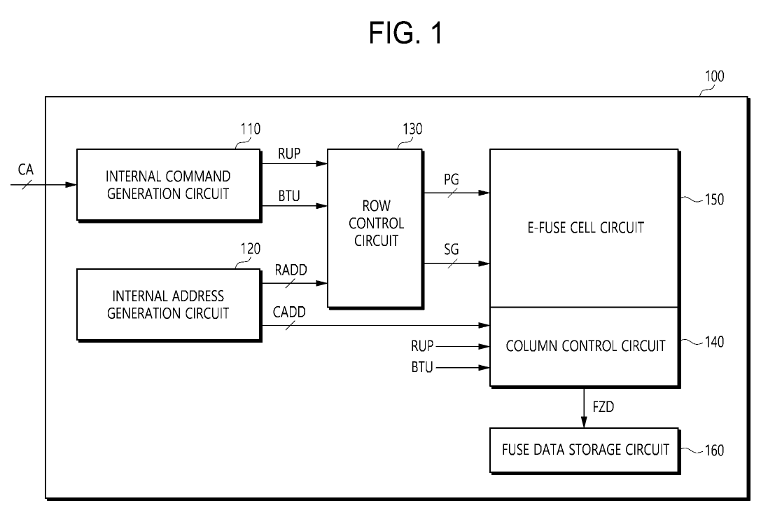

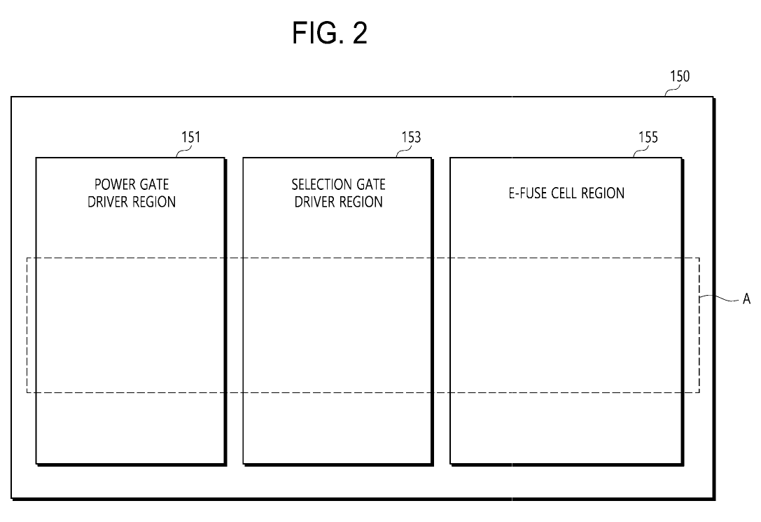

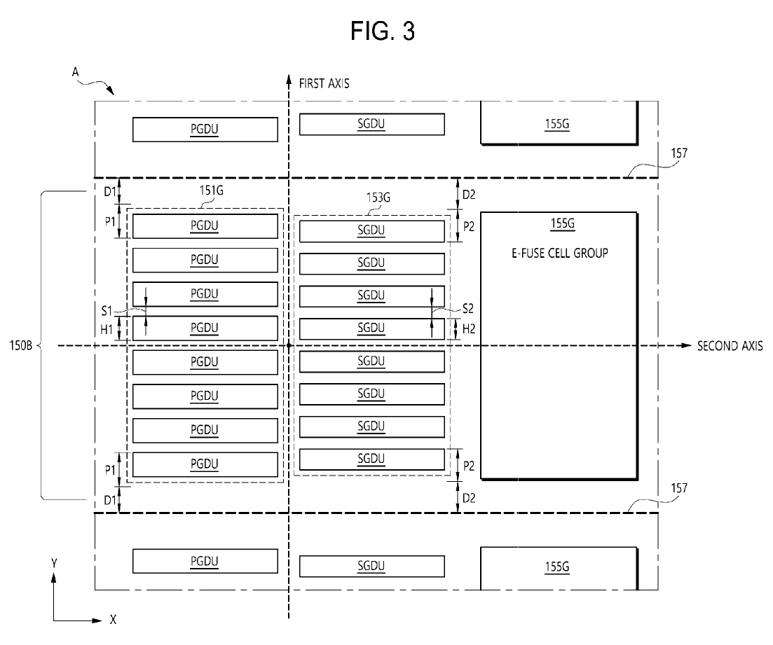

FIG. 1 is a view illustrating a semiconductor device 100 in accordance with embodiments of the present disclosure, FIG. 2 is a view illustrating an E-fuse cell circuit 150 in FIG. 1, and FIG. 3 is an enlarged view of a portion "A" in FIG. 2.

Referring to FIG. 1, the semiconductor device 100 may include an internal command generation circuit 110, an internal address generation circuit 120, a row control circuit 130, a column control circuit 140, an E-fuse cell circuit 150 and a fuse data storage circuit 160. The semiconductor device 100 may receive a command address CA from a controller (not shown) to perform various internal operations, such as a rupture operation, a boot-up operation, and the like. The number of bits of the command address CA may be changed depending on embodiments.

The internal command generation circuit 110 may generate a first internal command RUP and a second internal command BTU based on the command address CA.

The first internal command RUP may be activated when a first mode operation is performed. For example, the first mode operation may refer to a rupture operation to store fuse data FZD in a selected E-fuse cell among the E-fuse cells.

The second internal command BTU may be activated when a second mode operation is performed. For example, the second mode operation may refer to a boot-up operation to output the fuse data FZD stored in a selected E-fuse cell among the E-fuse cells.

In embodiments, the internal command generation circuit 110 may activate the first internal command RUP by decoding the command address CA having a logic level combination to perform the first mode operation. Further, the internal command generation circuit 110 may decode the command address CA having the logic level combination for performing the second mode operation to activate the second internal command BTU.

The internal address generation circuit 120 may generate a row address RADD and a column address (CADD) based on the command address CA. For example, the internal address generation circuit 120 may decode the command address CA to generate the row address RADD and the column address CADD. The number of bits in the row address RADD and the number of bits in the column address CADD may be changed in accordance with embodiments.

The row control circuit 130 may generate a power gate driver signal PG and a selection gate driver signal SG from the row address RADD based on the first internal command RUP and the second internal command BTU. For example, the row control circuit 130 may generate the power gate driver signal PG and the selection gate driver signal SG to program the E-fuse cell corresponding to a combination of logic levels at the row address RADD when the first mode operation (e.g., rupture operation) corresponding to the first internal command RUP is performed.

In addition, the row control circuit 130 may generate the power gate driver signal PG and the selection gate driver signal SG for extracting the fuse data FZD from the E-fuse cell corresponding to a logic level combination of the row address RADD when the second mode operation (e.g., a boot-up operation) corresponding to the second internal command BTU is performed.

The column control circuit 140 may selectively enable bit lines (not shown) by decoding the column address CADD based on the first internal command RUP and the second internal command BTU. For example, the column control circuit 140 may decode the column address CADD to enable the bit line (not shown) connected to the programmable E-fuse cell in the first mode operation corresponding to the first internal command RUP. Further, the column control circuit 140 may decode the column address CADD to enable the bit line (not shown) connected to the E-fuse cell targeted for the fuse data FZD readout in the second mode operation corresponding to the second internal command BTU.

The E-fuse cell circuit 150 may include a power gate driver region 151, a selection gate driver region 153 and an E-fuse cell region 155, as shown in FIG. 2. For example, the E-fuse cell circuit 150 may be configured to program the fuse data FZD into selected E-fuse cells based on the first internal command RUP, the power gate driver signal PG and the selection gate driver signal SG. Further, the E-fuse cell circuit 150 may output the fuse data FZD stored in the selected E-fuse cell based on the second internal command BTU, the power gate driver signal PG and the selection gate driver signal SG.

Referring to FIG. 3, the E-fuse cell circuit 150 may include E-fuse cell circuit blocks 150B. In embodiments, the E-fuse cell circuit blocks 150B may be spaced apart at a regular interval along a first direction (e.g., a Y direction).

The E-fuse cell circuit block 150B may include a power gate driver group 151G, a selection gate driver group 153G and an E-fuse cell group 155G. In embodiments, the power gate driver group 151G, the selection gate driver group 153G and the E-fuse cell group 155G may be spaced apart at regular intervals along a second direction (e.g., an X direction) perpendicular to the first direction.

In embodiments, the power gate driver group 151G and the selection gate driver group 153 may be arranged left and right relative to a first axis extending along the first direction.

The power gate driver group 151G may include a plurality of power gate driver units PGDUs. Further, the selection gate driver group 153G may include a plurality of selection gate driver units SGDUs. In embodiments, the plurality of power gate driver units PGDUs may be spaced apart upward and downward from the second axis, respectively, based on a center point of intersection between the first axis and a second axis extending along the second direction. Further, the plurality of selection gate driver units SGDUs may be spaced apart upward and downward from the second axis, respectively, based on the center point.

For example, the plurality of power gate driver units PGDUs may be arranged along the second axis with the upward and downward first pitch interval P1. The plurality of selection gate driver units SGDUs may be arranged along the second axis with the upward and downward second pitch interval P2, which differs from the first pitch interval P1.

The plurality of power gate driver units PGDUs arranged over the second axis and the plurality of power gate driver units PGDUs arranged under the second axis may be symmetrically arranged based on the second axis. In addition, the plurality of selection gate driver units SGDUs arranged over the second axis and the plurality of selection gate driver units SGDUs arranged under the second axis may be symmetrically arranged based on the second axis. For example, the first pitch interval P1 may be greater than the second pitch interval P2.

In embodiments, the plurality of power gate driver units PGDUs and the plurality of selection gate driver units SGDUs included in the E-fuse cell circuit block 150B may be respectively arranged in a first region and a second region, which are divided by the first axis among four regions divided based on the center point where the first and second axes are intersected with each other, and arranged to have different pitch intervals.

For example, the plurality of power gate driver units PGDUs may be arranged to have the first pitch interval P1 and the plurality of selection gate driver units SGDUs may be arranged to have the second pitch interval P2. The first pitch interval P1 may include a height H1 of the power gate driver unit and a space S1 between adjacent power gate driver units. The second pitch interval P2 may include a height H2 of the selection gate driver unit and a space S2 between adjacent selection gate driver units. In embodiments, the space S1 between the power gate driver units PGDUs may be smaller than the space S2 between the selection gate driver units, because the height H1 of the power gate driver unit is greater than the height H2 of the height of the selection gate driver unit.

This may enable an efficient layout of E-fuse cell arrays, the selection gate drivers and the power gate drivers in a limited area while satisfying reliability of the power gate driver.

Referring again to FIG. 3, the E-fuse cell circuit 150 may include at least one structure 157 disposed between adjacent E-fuse cell circuit blocks 150B. In embodiments, the structures 157 may include at least one of a well pick-up line and a dummy pattern.

The at least two power gate driver units PGDUs closest to the structure 157, among the plurality of power gate driver units PGDUs, may each be spaced apart from the structure 157 by a first distance D1. The at least two selection gate driver units SGDUs closest to the structure 157, among the plurality of selection gate driver units SGDUs, may each be spaced apart from the structure 157 by a second distance D2 that is different from the first distance D1. In this case, the first distance D1 may be smaller than the second distance D2, but embodiments of the present disclosure are not particularly limited thereto.

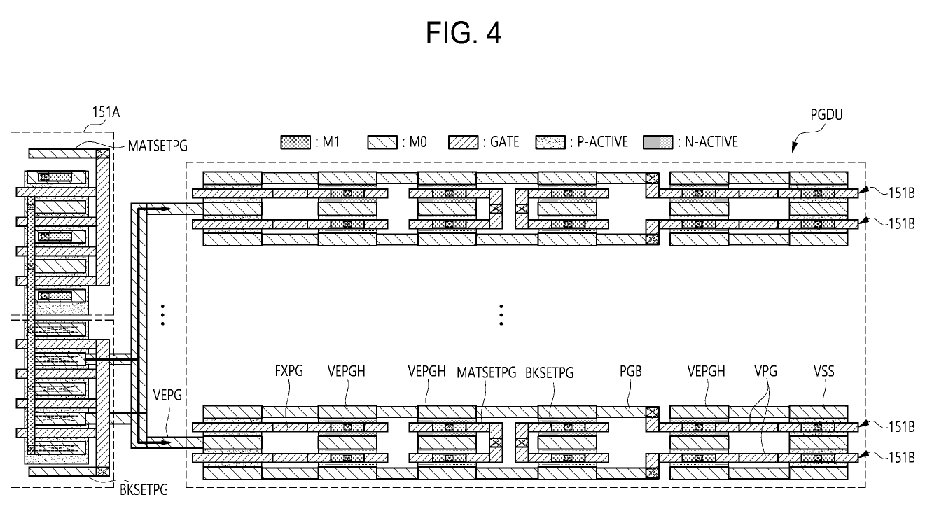

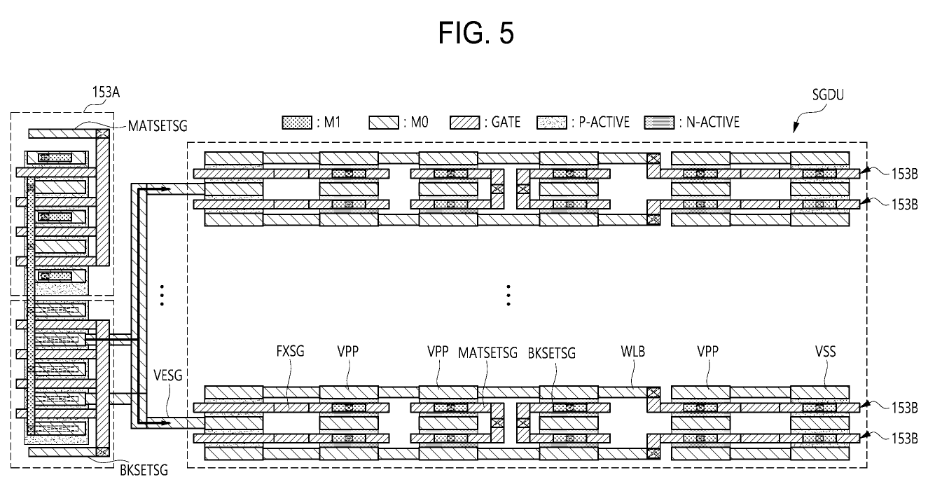

FIG. 4 is a layout illustrating a power gate driver unit PGDU in accordance with embodiments of the present disclosure, and FIG. 5 is a layout illustrating a selection gate driver unit SGDU in accordance with embodiments of the present disclosure.

Referring first to FIG. 4, the power gate driver unit PGDU may include a power gate voltage activation circuit 151A, and a plurality of power gate voltage output circuits 151B.

The plurality of power gate voltage output circuits 151B may be connected to an output terminal of the power gate voltage activation circuit 151A. The power gate driver unit PGDU may also be referred to as a programming driver unit. In embodiments, the number of the plurality of power gate voltage output circuits 151B may be N, where N is an even number equal to or greater than 2, but the embodiments of the present disclosure are not particularly limited thereto.

For example, an input terminal of the power gate voltage activation circuit 151A may receive a voltage, and the output terminal of the power gate voltage activation circuit 151A may be connected to the plurality of power gate voltage output circuits 151B. The output terminal of the power gate voltage activation circuit 151A and the plurality of power gate voltage output circuits 151B may be connected via a metal interconnection M0 connected with a source region (not shown).

Further, for example, the power gate voltage activation circuit 151A may be configured to be enabled or disabled based on a logic level (high or low) of a first address signal MATSETPG and a second address signal BKSETPG. For example, when the power gate voltage activation circuit 151A may be activated, a voltage VEPG connected to the input of the power gate voltage activation circuit 151A may be activated and provided to the plurality of power gate voltage output circuits 151B. In this case, the voltage connected to the input terminal of the power gate voltage activation circuit 151A may be at least one of a supply voltage VEPGH and a ground voltage VSS.

Each of the plurality of power gate voltage activation circuits 151A may be configured to output the power gate voltage VEPG to a power gate of a corresponding E-fuse cell based on the voltage VEPG provided from the power gate voltage activation circuits 151A and a logic level (high or low) of a third address signal FXPG. Here, the power gate voltage VEPG may be the supply voltage VEPGH or the ground voltage VSS. For example, the supply voltage VEPGH output to the power gate of the E-fuse cell may be 5 V and the ground voltage VSS may be 0 V, but embodiments of the present disclosure are not particularly limited thereto.

Referring to FIG. 5, the layout structure of the selection gate driver unit SGDU may be substantially the same as that of the power gate driver unit PGDU described above; however, the embodiments of the present disclosure are not limited thereto. The selection gate driver unit SGDU may also be referred to as a word line driver unit

For example, the selection gate driver unit SGDU may include one selection gate voltage activation circuit 153A and a plurality of selection gate voltage output circuits 153B connected to an output terminal of the one selection gate voltage activation circuit 153A. In embodiments, the number of the plurality of selection gate voltage output circuits 153B may be N, where N is an even number equal to or greater than 2, but embodiments of the present disclosure are not particularly limited thereto.

For example, the input terminal of the selection gate voltage activation circuit 153A may be connected to a voltage and the output terminal may be connected to a plurality of selection gate voltage output circuits 153B. The output terminal of the selection gate voltage activation circuit 153A and the plurality of selection gate voltage output circuits 153B may be connected via a metal interconnection M0 connected with a source region (not shown).

Further, the selection gate voltage activation circuit 153A may be configured to be enabled or disabled based on the logic level (high or low) of the first address signal MATSETSG and the second address signal BKSETSG. For example, when the selection gate voltage activation circuit 153A may be activated, a voltage VESG connected to the input of the selection gate voltage activation circuit 153A may be enabled and provided to a plurality of selection gate voltage output circuits 153B. In this case, the voltage connected to the input of the selection gate voltage activation circuit 153A may be at least one of a supply voltage VPP and a ground voltage VSS.

Each of the plurality of selection gate voltage activation circuits 153A may be configured to output a selection gate voltage VSG to a corresponding selection gate of the E-fuse cell based on a voltage VESG provided from the selection gate voltage activation circuit 153A and a logic level (high or low) of the third address signal FXSG. The selection gate voltage VSG may be the supply voltage VPP or the ground voltage VSS. For example, the supply voltage VPP output to the selection gate of the E-fuse cell may be about 2 V and the ground voltage VSS may be about 0 V, but embodiments of the present disclosure are not particularly limited thereto.

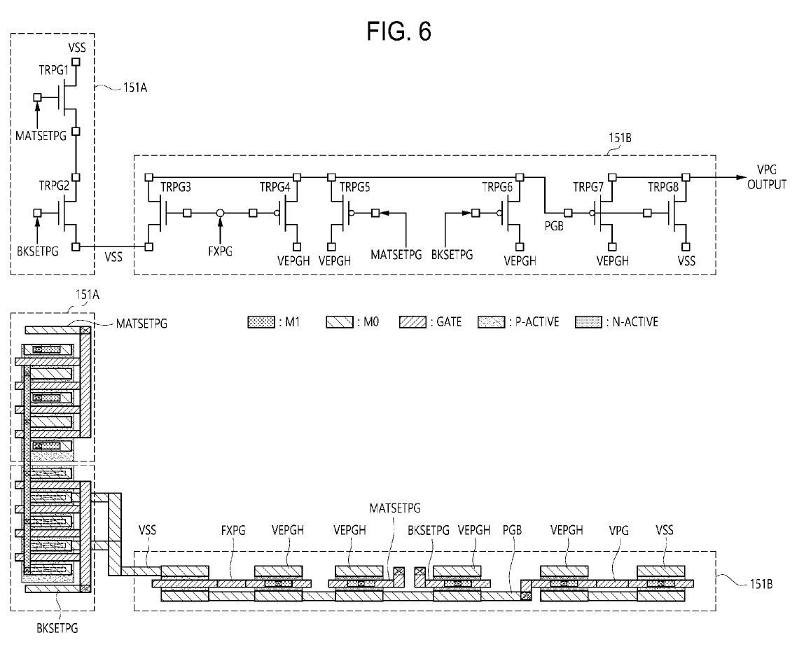

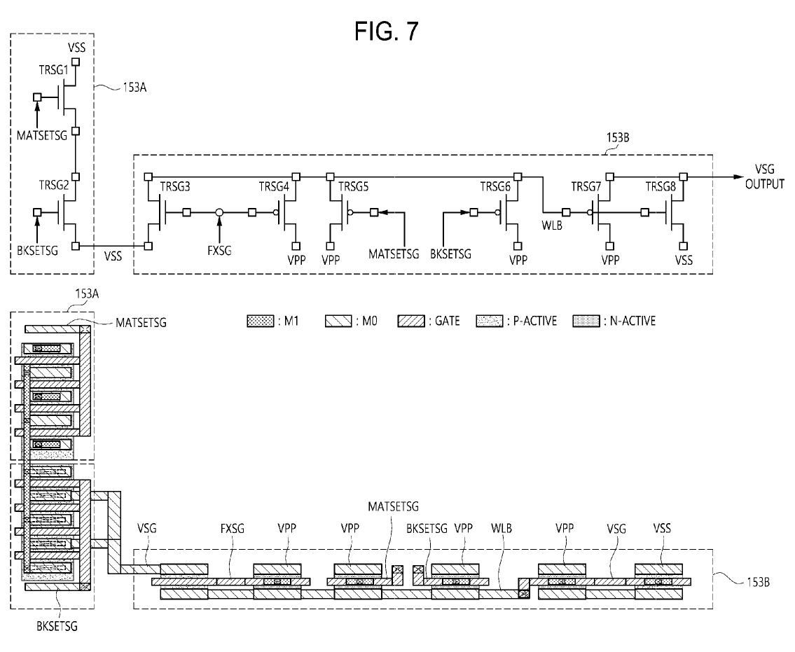

FIG. 6 is a layout and a circuit diagram illustrating a power gate voltage activation circuit and a power gate voltage output circuit of a power gate driver unit in accordance with embodiments of the present disclosure, and FIG. 7 is a layout and a circuit diagram illustrating showing a selection gate voltage activation circuit and a selection gate voltage output circuit of a selection gate driver unit in accordance with embodiments of the present disclosure. For conveniences, in FIGS. 6 and 7 an input terminal of the power gate voltage activation circuit and an input terminal of the selection gate activation circuit may receive a ground voltage VSS, respectively. It will be appreciated that embodiments of the present disclosure are not limited to the layout diagrams and schematics illustrated in FIGS. 6 and 7, and may be implemented in various configurations.

Referring to FIG. 6, the power gate voltage activation circuit 151A may include a first NMOS transistor TRPG1 and a second NMOS transistor TRPG2 connected in series. The first NMOS transistor TRPG1 may include an input terminal (e.g., source) connected to a ground voltage VSS, a gate through which the first address information MATSETPG may be inputted, and an output terminal (e.g., drain) connected to an input terminal of the second NMOS transistor TRPG2. Further, the second NMOS transistor TRPG2 may include an input terminal (e.g., a drain) connected to the output terminal of the first NMOS transistor TRPG1, a gate into which the second address information BKSETPG may be inputted, and an output terminal (e.g., a source) connected to the power gate voltage output circuit 151B.

The power gate voltage activation circuit 151A may enable or disable the ground voltage VSS connected to the input of the first NMOS transistor TRPG1 depending on the logic levels (high and low) of the first address information MATSETPG and the second address information BKSETPG. For example, the first address information MATSETPG may be address information connected with a MAT in which the accessed E-fuse cell may be located, and the second address information BKSETPG may be address information connected with a BANK in which the accessed E-fuse cell may be located.

For example, if the logic levels of the first address information MATSETPG and the second address information BKSETPG may be both high, the ground voltage VSS connected to the input terminal of the first NMOS transistor TRPG1 may be activated and provided to the power gate voltage output circuit 151B.

The power gate voltage output circuit 151B may include a third NMOS transistor TRPG3 and a first PMOS transistor TRPG4 that may be turned on or off in accordance with the logic levels (high and low) of the third address information FXPG, a second NMOS transistor TRPG5 that may be turned on or off in accordance with the logic level of the first address information MATSETPG, and a third PMOS transistor TRPG6 that may be turned on or off in accordance with the logic level of the second address information BKSETPG, a third PMOS transistor TRPG6 that may be turned on or off based on a logic level of the second address information BKSETPG, and a fourth PMOS transistor TRPG7 and a fourth NMOS transistor TRPG8 that may be turned on or off based on a level of voltage input through the input voltage terminal PGB. Here, the third address information FXPG may be the word line address information to which the accessed E-fuse cell is connected.

For example, when the logic levels of the first to third address information MATSETPG, BKSETPG and FXPG may be all high, the third NMOS transistor TRPG3 may be turned on, and the first to third PMOS transistors TRPG4, TRPG5 and TRPG6 may be turned off. Accordingly, the input voltage terminal PGB may apply the ground voltage VSS to the gate of each of the fourth PMOS transistor TRPG7 and the fourth NMOS transistor TRPG8, resulting in the fourth PMOS transistor TRPG7 being turned on and the fourth NMOS transistor TRPG8 being turned off, and the supply voltage VEPGH may be outputted as the power gate voltage VPG. As the supply voltage VEPGH may be output as the power gate voltage VPG, the accessed E-fuse cell may be programmed.

Referring to FIG. 7, the selection gate voltage activation circuit 153A may include a first NMOS transistor TRSG1 and a second NMOS transistor TRSG2 connected in series. The first NMOS transistor TRSG1 may include an input terminal connected to a ground voltage VSS, a gate into which the first address information MATSETSG may be inputted, and an output terminal connected to an input terminal of the second NMOS transistor TRSG2. Further, the second NMOS transistor TRSG2 may include an input stage connected to the output stage of the first NMOS transistor TRSG1, a gate into which the second address information BKSETSG may be inputted, and an output stage connected to the selection gate voltage output circuit 153B.

Further, the selection gate voltage output circuit 153B may include a third NMOS transistor TRSG3 and a first PMOS transistor TRSG4 that may be turned on or off in accordance with the logic levels (high and low) of the third address information FXSG, a second PMOS transistor TRSG5 that may be turned on or off in accordance with the logic level of the first address information MATSETSG, and an input voltage terminal WLB, a third PMOS transistor TRSG6 that may be turned on or turned off depending on the logic level of the second address information BKSETSG, and a fourth PMOS transistor TRSG7 and a fourth NMOS transistor TRSG8 that may be turned on or turned off depending on the level of the voltage input through the input voltage terminal WLB.

The configuration of the selection gate voltage activation circuit 153A and the selection gate voltage output circuit 153B is the same as the configuration of the power gate voltage activation circuit 151A and the power gate voltage output circuit 151B, respectively. Accordingly, a detailed description of the operation of each of the selection gate voltage activation circuit 153A and the selection gate voltage output circuit 153B will be omitted.

The fuse data storage circuit 160 may be configured to store the fuse data FZD output from the E-fuse cell circuit 150.

While the present invention has been described in detail with reference to specific embodiments, the present invention is not limited to the above embodiments, and is capable of many modifications within the scope of the present disclosure by those having ordinary skill in the art. Furthermore, the embodiments may be combined to form additional embodiments.

What is claimed is:

1. An E-fuse cell circuit comprising a plurality of E-fuse cell circuit blocks arranged spaced apart with each other along a first direction,
wherein each of the plurality of E-fuse cell circuit blocks comprises:
an E-fuse cell group including a plurality of E-Fuse cells;
a selection gate driver group disposed adjacent to the E-fuse cell group along a second direction perpendicular to the first direction, the selection gate driver group including a plurality of selection gate driver units configured to provide a selection gate voltage signal to at least one E-fuse cell selected among the plurality of E-fuse cells; and
a power gate driver group disposed adjacent to the selection gate driver group along the second direction, the power gate driver group including a plurality of power gate driver units configured to provide a power gate voltage signal to the at least one E-fuse cell,
wherein the plurality of power gate driver units are arranged with a first pitch interval in upward and downward directions from a second axis extending along the second direction, based on a center point of an intersection between the second axis and a first axis extending along the first direction; and
wherein the plurality of selection gate driver units are arranged with a second pitch interval in the upward and downward directions from the second axis based on the center point, the second pitch interval being different from the first pitch interval.

2. The E-fuse cell circuit of claim 1, wherein the first pitch interval is greater than the second pitch interval.

3. The E-fuse cell circuit of claim 1, further comprising at least one structure disposed between adjacent E-fuse cell circuit blocks.

4. The E-fuse cell circuit of claim 3, wherein the at least one structure comprises at least one of a well pick-up line and a dummy pattern.

5. The E-fuse cell circuit of claim 3, wherein at least two power gate driver units closest to the at least one structure, among the plurality of power gate driver units, are spaced apart from the at least one structure by a first distance, respectively; and
wherein at least two selection gate driver units closest to the at least one structure, among the plurality of selection gate driver units, are spaced apart from the at least one structure by a second distance different from the first distance, respectively.

6. The E-fuse cell circuit of claim 5, wherein the first distance is smaller than the second distance.

7. The E-fuse cell circuit of claim 1, wherein each of the plurality of selection gate driver units comprises:
a selection gate voltage activation circuit; and
N selection gate voltage output circuits connected to an output terminal of the selection gate voltage activation circuit to output a voltage to a selection gate of the at least one E-fuse cell, where N is an even number equal to or greater than 2.

8. The E-fuse cell circuit of claim 7, wherein the output terminal of the selection gate voltage activation circuit and each of the N selection gate voltage output circuits are electrically connected via a metal interconnection connected with a source region.

9. The E-fuse cell circuit of claim 1, wherein each of the plurality of power gate driver units comprises:
a power gate voltage activation circuit; and
N power gate voltage output circuits connected to an output terminal of the power gate voltage activation circuit to output a voltage to a power gate of the at least one E-fuse cell, wherein N is an even number equal to or greater than 2.

10. The E-fuse cell circuit of claim 9, wherein the output terminal of the power gate voltage activation circuit and each of the N power gate voltage output circuits are electrically connected via a metal interconnection connected with a source region.

11. A semiconductor device comprising:
at least one E-fuse cell group each including a plurality of E-Fuse cells;
at least one power gate driver group corresponding to the at least one E-fuse cell group and each including a plurality of power gate driver units; and
at least one selection gate driver group corresponding to the at least one E-fuse cell group and each including a plurality of selection gate driver units,
wherein the at least one power gate driver group and the at least one selection gate driver group are arranged left and right based on a first axis extending in a first direction,
wherein the plurality of power gate driver units are arranged at a first pitch interval in upward and downward directions from a second axis perpendicular to the first axis; and
wherein the plurality of selection gate driver units are arranged in the upward and downward direction of the second axis from a second pitch interval different from the first pitch interval.

12. The semiconductor device of claim 11, wherein the first pitch interval is greater than the second pitch interval.

13. The semiconductor device of claim 11, further comprising at least one structure disposed between E-fuse cell groups adjacent in a second direction perpendicular to the first direction, when the at least one E-fuse cell group is plural.

14. The semiconductor device of claim 13, wherein the at least one structure comprises at least one of a well pick-up line and a dummy pattern.

15. The semiconductor device of claim 11, wherein each of the plurality of power gate driver units comprises:
a power gate voltage activation circuit; and
N power gate voltage output circuits connected to an output terminal of the power gate voltage activation circuit to output a voltage to a power gate of the at least one E-fuse cell, where N is an even number equal to or greater than 2.

16. The semiconductor device of claim 15, wherein the output terminal of the power gate voltage activation circuit and each of the N power gate voltage output circuits are electrically connected via a metal interconnection connected with a source region.

17. The semiconductor device of claim 11, wherein each of the plurality of selection gate driver units comprises:
a selection gate voltage activation circuit; and
N selection gate voltage output circuits connected to an output terminal of the selection gate voltage activation circuit to output a voltage to a selection gate of the at least one E-fuse cell, where N is an even number equal to or greater than 2.

18. The semiconductor device of claim 17, wherein the output terminal of the selection gate voltage activation circuit and each of the N selection gate voltage output circuits are electrically connected via a metal interconnection connected with a source region.
